(19) United States
(12) Patent Application Publication
(10) Pub. No.: US 2008/0111920 A1
(43) Pub. Date: May 15, 2008

(54) VERTICAL FREQUENCY DISTINCTION CIRCUIT, VIDEO DISPLAY APPARATUS, AND VERTICAL FREQUENCY DISTINCTION METHOD

(75) Inventors: Sachi OTA, Osaka (JP); Norihide KINUGASA, Kyoto (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/874,387

(22) Filed: Oct. 18, 2007

(30) Foreign Application Priority Data
Oct. 18, 2006 (JP) JP 2006-283641

(51) Int. Cl. H03L 7/00; H04N 5/94

(52) U.S. Cl. 348/548; 348/547

(57) ABSTRACT

There is provided a vertical frequency distinction circuit and a vertical frequency distinction method capable of reducing a chip area, and a video display apparatus having the vertical frequency distinction circuit. A vertical control pulse generating section of the vertical frequency distinction circuit generates a noise eliminating signal for disabling input of noise during a predetermined period until arrival of a vertical synchronization signal. A distinction result latch section samples the noise eliminating signal and an inversion signal of the noise eliminating signal at the timing of input of the vertical synchronization signal, to generate two output signals. An output selecting section selects either one of the two output signals of the distinction result latch section based on a mode setting signal, to output the selected signal as a distinction result signal.

### BACKGROUND OF THE INVENTION

1. Field of the Invention

The present invention relates to a vertical frequency distinction circuit and a vertical frequency distinction method that discriminates a frequency of a vertical synchronization signal included in a video signal, and a video display apparatus having the vertical frequency distinction circuit.

2. Related Art

A video display apparatus generates a vertical control timing pulse signal typically by using a vertical synchronization signal included in a video signal as a reference, and displays an image based on the timing pulse signal. The frequency of the vertical synchronization signal is 60 Hz (1 V=262.5H) in the case of an NTSC system, and 50 Hz (1 V=312.5H) in the case of a PAL system. As thus described, the frequency of the vertical synchronization signal differs between the NTSC system and the PAL system.

For allowing generation of a variety of timing pulse signals suitable respectively for the NTSC system and the PAL system, the video display apparatus needs to operate in settings suitable respectively for the NTSC system and the PAL system. For this reason, a vertical frequency distinction circuit that discriminates a frequency of a vertical synchronization signal is provided in the video display apparatus. This vertical frequency distinction circuit has a counter to be used for discriminating a frequency of a vertical synchronization signal (for example, JP-A-61-30181 (patent document 1), and JP-A-2-194774 (patent document 2)).

A counter of a field frequency distinction circuit (vertical frequency distinction circuit) of the patent document 1 counts the number of horizontal synchronization signals with respect to each period of a vertical synchronization signal. This vertical frequency distinction circuit determines that the frequency is 60 Hz when a count value of the counter is not larger than 262.5, and 50 Hz when the counter value is not smaller than 312.5.

A vertical synchronization circuit of the patent document 2 has: a vertical counter which is reset based on arrival of a vertical synchronization signal; and a frequency distinction circuit (vertical frequency distinction circuit) which is provided with a counter for counting output of the vertical counter to discriminate a frequency. The counter of the vertical frequency distinction circuit counts period range detecting signals based respectively upon a vertical synchronization signal of 50 Hz and a vertical synchronization signal of 60 Hz which are outputted from the vertical counter. This period distinction circuit determines whether the frequency is 50 Hz or 60 Hz by counting the period range detecting signals of 50 Hz or 60 Hz sequentially several times. Further, in the vertical synchronization circuit of the patent document 2, in order to prevent erroneous resetting of the vertical counter due to noise inputted at a timing other than the timing of arrival of the vertical synchronization signal, a period is set in which acceptance of input of a vertical synchronization signal is disabled based on a distinction result of the vertical frequency distinction circuit.

The vertical frequency distinction circuits of the patent documents 1 and 2 have the counters specifically for discriminating a frequency. The video display apparatus is typically provided with a counter that is reset by a vertical synchronization signal, such as the vertical counter of the patent document 2, for the purpose of generating vertical control timing pulse signals. For this reason, when the vertical frequency distinction circuit of the patent document 1 or 2 is mounted in the video display apparatus, the counter to be used for discriminating a frequency is mounted in addition to the counter to be used for generating vertical control timing pulse signals, thereby causing a problem of increasing a chip area at the time of integration.

### SUMMARY OF THE INVENTION

The present invention is made for solving the above problem, and has an object to provide a vertical frequency distinction circuit and a vertical frequency distinction method for reducing a chip area, and a video display apparatus provided with the vertical frequency distinction circuit.

A vertical frequency distinction circuit of the present invention has: a vertical control pulse generating section which includes a counter that counts a horizontal synchronization signal and is reset based on a vertical synchronization signal, and generates vertical control timing pulse signals based on output of the counter; and a frequency distinction unit of discriminating a frequency of a vertical synchronization signal. The vertical control pulse generating section generates, based on a count value of the counter, a noise eliminating signal for preventing the counter from being reset due to noise during a predetermined period from arrival of a vertical synchronization signal until arrival of a next vertical synchronization signal, and the frequency distinction unit generates and outputs a distinction result signal that identifies the frequency of the vertical synchronization signal based on the noise eliminating signal. Here, the “frequency distinction unit” corresponds to a “distinction result latch section 200” and an “output selecting section 300” of an embodiment. The “noise eliminating signal” corresponds to a “first noise eliminating signal VSC” of the embodiment.

A video display apparatus of the present invention has: a synchronization separation circuit which extracts a horizontal synchronization signal and a vertical synchronization signal from an input signal; the vertical frequency distinction circuit which discriminates a frequency of the vertical synchronization signal based on the horizontal synchronization signal and the vertical synchronization signal, and also generates vertical control timing pulse signals based on the discrimination result of the frequency; and a horizontal control pulse generating section which generates horizontal control timing pulse signals based on the horizontal synchronization signal.

A vertical frequency distinction method of the present invention has: generating a noise eliminating signal for preventing the counter, which is used for generating vertical control pulse signals, being reset erroneously due to noise during a predetermined period from arrival of a vertical synchronization signal until arrival of a next vertical synchronization signal; and outputting a distinction result signal which identifies the frequency of the vertical synchronization signal by sampling the noise eliminating signal based on the vertical synchronization signal.

According to the present invention, a noise eliminating signal for preventing a counter, which is used for generating vertical control timing pulse signals, from being reset erroneously due to noise is generated so as to remain at a High level and a Low level for predetermined periods. The noise eliminating signal is sampled at the timing of arrival of a vertical synchronization signal, to generate a distinction result signal showing a discrimination result of a frequency. With this configuration, the counter specifically for discriminating a frequency becomes unnecessary, and thereby chip area of the vertical frequency distinction circuit to be mounted in the video display apparatus can be reduced.

### BRIEF DESCRIPTION OF THE DRAWINGS

FIG. 1 is a configuration view of a video display apparatus of the present invention;

FIG. 2 is a configuration view of a vertical frequency distinction circuit of FIG. 1;

FIG. 3 is a configuration view of a vertical control pulse generating section of FIG. 2;

FIG. 4A is a truth value table of a self-reset generating section; and FIG. 4B is a truth value table of an external reset generating section;

FIG. 5 is a flowchart showing a color system setting method of the present invention;

FIG. 6 is a timing diagram showing an operation of the vertical control pulse generating section in a case where the vertical frequency distinction circuit is set in an NTSC mode;

FIG. 7 is a timing diagram showing an operation of the vertical control pulse generating section in a case where the vertical frequency distinction circuit is set in a PAL mode;

FIG. 8 is a timing diagram showing an operation of the vertical frequency distinction circuit in a case where the vertical frequency distinction circuit is set in the NTSC mode; and

FIG. 9 is a timing diagram showing an operation of the vertical frequency distinction circuit in a case where the vertical frequency distinction circuit is set in the PAL mode.

### DETAILED DESCRIPTION OF THE PREFERRED EMBODIMENTS

In the following, an embodiment of the present invention is described with reference to drawings.

### 1. Configuration

### 1.1 Whole Configuration of Video Display Apparatus

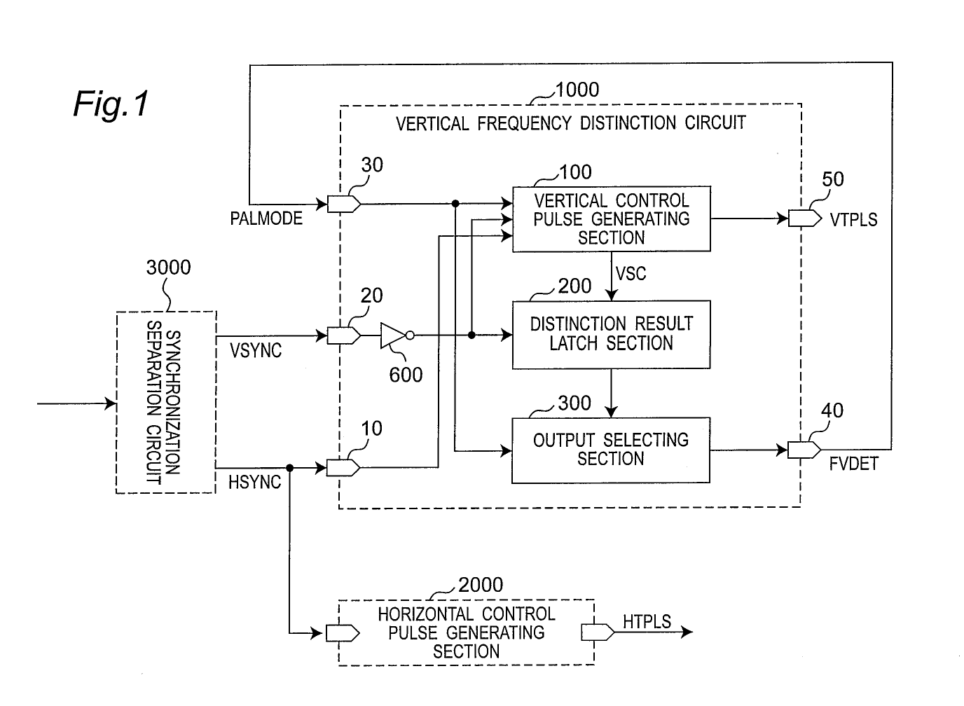

FIG. 1 shows a video display apparatus of an embodiment of the present invention. The video display apparatus of the present embodiment can receive either a video signal in the NTSC system (frequency of 60 Hz, 1 V=262.5H) or a video signal in the PAL system (frequency of 50 Hz, 1 V=312.5H). The video display apparatus has a function of automatically discriminating the kind of the video signal (NTSC or PAL), and automatically changing internal setting in accordance with the kind of the video signal.

The video display apparatus of the present embodiment has: a synchronization separation circuit 3000 which extracts a horizontal synchronization signal HSYNC and a vertical synchronization signal VSYNC from an input video signal; a vertical frequency distinction circuit 1000 which generates vertical control timing pulse signals VTPLS based on the extracted horizontal synchronization signal HSYNC and vertical synchronization signal VSYNC and also outputs a distinction result signal FVDET for discriminating whether the input video signal is made in the NTSC system or the PAL system; and a horizontal control pulse generating section 2000 which generates horizontal control timing pulse signals HTPLS based on the extracted horizontal synchronization signal HSYNC.

The vertical frequency distinction circuit 1000 inputs the horizontal synchronization signal HSYNC, extracted by the synchronization separation circuit 3000, from an input terminal 10, and inputs the vertical synchronization signal VSYNC, extracted by the synchronization separation circuit 3000, from an input terminal 20. The inputted vertical synchronization signal VSYNC is inverted by an inverter 600. Further, the vertical frequency distinction circuit 1000 inputs, from an input terminal 30, a mode setting signal PALMODE for controlling whether a variety of settings in the internal circuit should be set for the PAL mode or for the NTSC mode.

The vertical frequency distinction circuit 1000 has a vertical control pulse generating section 100 that generates the vertical control timing pulse signals VTPLS necessary for video display based on the inputted vertical synchronization signal VSYNC and horizontal synchronization signal HSYNC. The vertical frequency distinction circuit 1000 outputs the generated vertical control timing pulse signals VTPLS from the output terminal 50. The vertical control timing pulse signals VTPLS are generated based on the mode setting signal PALMODE inputted from the input terminal 30.

Further, in order to prevent noise from occurring at a timing other than the timing of arrival of the vertical synchronization signal VSYNC and the noise having occurred from exerting an effect on the vertical control timing pulse signals VTPLS, the vertical control pulse generating section 100 generates a first noise eliminating signal VSC for setting a period in which input of a vertical synchronization signal VSYNC is acceptable.

The vertical frequency distinction circuit 1000 of the present embodiment does not have a counter specifically for discriminating whether the input video signal is in the NTSC system or the PAL system, but has a distinction result latch section 200 and an output selecting section 300 for discriminating whether the video signal is in the NTSC system or the PAL system. In the distinction result latch section 200 and the output selecting section 300, the discrimination between the NTSC system and the PAL system is performed by using the first noise eliminating signal VSC outputted from the vertical control pulse generating section 100. The vertical frequency distinction circuit 1000 outputs a result of the discrimination between the NTSC system and the PAL system from an output terminal 40 as a distinction result signal FVDET. The video display apparatus of the present embodiment feeds the distinction result signal FVDET of the vertical frequency distinction circuit 1000 back to the mode setting signal PALMODE, to automatically set a variety of settings inside the vertical control pulse generating section 100 to settings value for the NTSC mode or the PAL mode based on the frequency distinction result.

A schematic operation of the video display apparatus shown in FIG. 1 is described. When inputting a video signal, the video display apparatus extracts the horizontal synchronization signal HSYNC and the vertical synchronization signal VSYNC from the inputted video signal by means of the synchronization separation circuit 3000. The horizontal control pulse generating section 2000 generates the horizontal control timing pulse signals HTPLS based on the horizontal synchronization signal HSYNC. The vertical frequency distinction circuit 1000 generates the first noise eliminating signal VSC based on the horizontal synchronization signal HSYNC and the vertical synchronization signal VSYNC, and generates the distinction result signal FVDET based on the first noise eliminating signal VSC. By feeding the distinction result signal FVDET back to the mode setting signal PALMODE, the video display apparatus automatically sets a color system of the vertical frequency distinction circuit 1000 either for the PAL mode of 50 Hz or the NTSC mode of 60 Hz. The vertical control pulse generating section 100 generates the vertical control timing pulse signals VTPLS in accordance with the set mode.

### 1.2 Configuration of Vertical Frequency Distinction Circuit

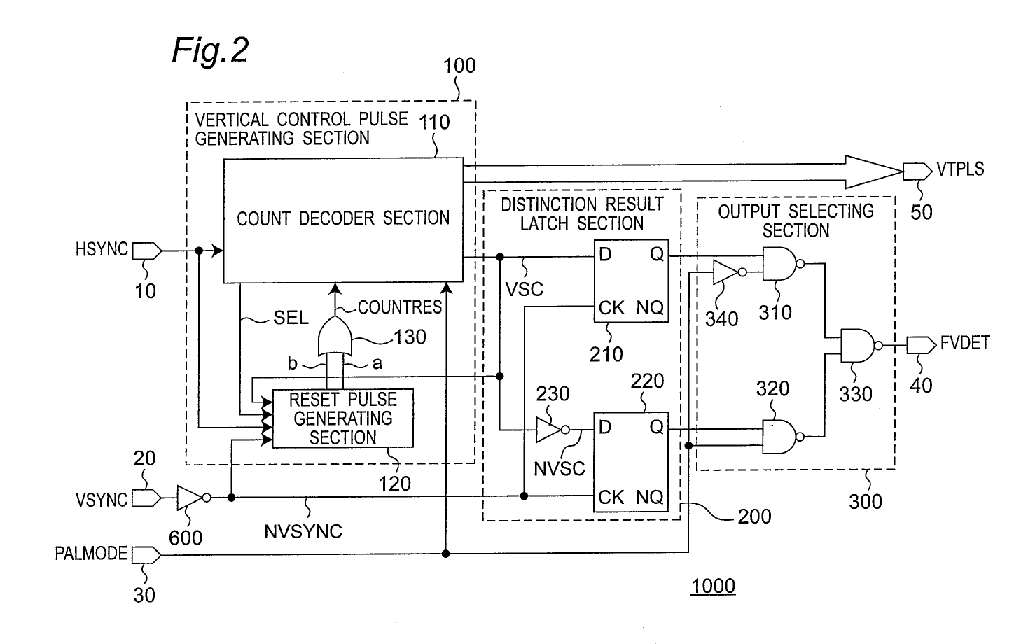

The internal configuration of the vertical frequency distinction circuit 1000 is described which generates the first noise eliminating signal VSC and discriminates a frequency by using the first noise eliminating signal VSC. FIG. 2 shows the concrete internal configuration of the vertical frequency distinction circuit 1000.

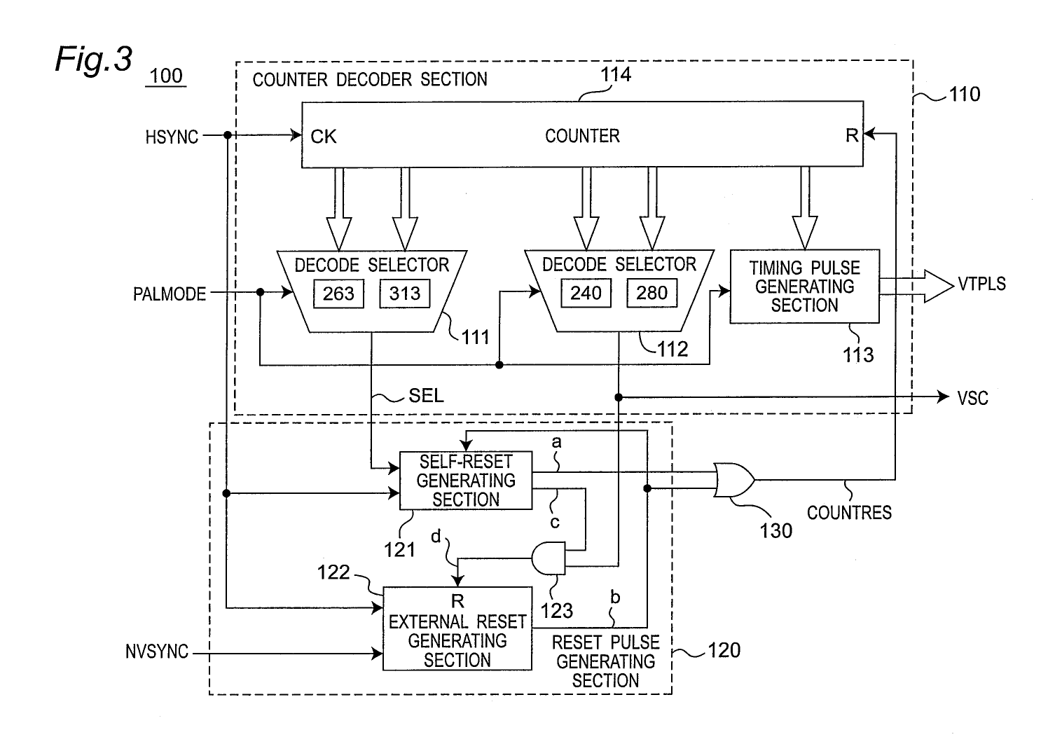

The vertical control pulse generating section 100 has: a count decoder section 110 which counts the horizontal synchronization signal HSYNC to generate the vertical control timing pulse signals VTPLS and the first noise eliminating signal VSC; and a reset pulse generating section 120 which generates signals a and b for resetting a count value of the count decoder section 110. The signals “a” and “b” are inputted as a reset signal COUNTRES into the count decoder section 110 through an OR gate 130. The details of count decoder section 110 and the reset pulse generating section 120 are described later along with FIG. 3.

The distinction result latch section 200 has a D-type flip-flops 210 and 220 for latching the first noise eliminating signal VSC that is outputted from the vertical control pulse generating section 100, and an inverter 230 connected to a data input terminal of the flip-flop 220. The first noise eliminating signal VSC outputted from the count decoder section 110 is inputted into a data input terminal of the flip-flop 210 and the data input terminal of the flip-flop 220 via the inverter 230. An inversion signal NVSYNC of the vertical synchronization signal VSYNC is inputted into clock terminals of the flip-flops 210 and 220.

The output selecting section 300 selects one of two outputs of the distinction result latch section 200 and outputs the selected one as the distinction result signal FVDET such that the level of the distinction result signal FVDET showing that the input signal is an NTSC signal and the level of the distinction result signal FVDET showing that the input signal is a PAL signal are made constant, respectively. The output selecting section 300 has NAND gates 310, 320 and 330, and an inverter 340 connected to an internal terminal of the NAND gate 310.

Into the NAND gate 310, a signal outputted from an output terminal Q of the flip-flop 210 is inputted, and the mode setting signal PALMODE is inputted thorough the inverter 340. Into the NAND gate 320, a signal outputted from an output terminal Q of the flip-flop 220 and the mode setting signal PALMODE are inputted. Output signals of the NAND gates 310 and 320 are inputted into the NAND gate 330, and an output signal of the NAND gate 330 is outputted as the distinction result signal FVDET to the output terminal 40.

When the mode setting signal PALMODE is “High” (PAL mode), the output signal of the flip-flop 220 inputted into the NAND gate 320 becomes the distinction result signal FVDET. When the mode setting signal PALMODE is “Low” (NTSC mode), the output signal of the flip-flop 210 inputted into the NAND gate 310 becomes the distinction result signal FVDET.

### 1.3 Configuration of Vertical Control Pulse Generating Section

FIG. 3 shows internal configurations of the count decoder section 110 and the reset pulse generating section 120 in the vertical control pulse generating section 100.

### 1.3.1 Configuration of Count Decoder Section

The count decoder section 110 has: a counter 114 that counts the horizontal synchronization signal HSYNC; and a timing pulse generating section 113 that generates the vertical control timing pulse signals VTPLS based on output of the counter 114 in a mode in accordance with the mode setting signal PALMODE. The counter 114 counts the horizontal synchronization signal HSYNC that is inputted into a clock terminal thereof, and is reset by the reset signal COUNTRES that is inputted into a reset terminal thereof.

The reset signal COUNTRES is made up of two kinds of reset signals “a” and “b”. The reset signal “b” is an external reset signal for resetting the counter 114 based on the timing of arrival of the vertical synchronization signal VSYNC. The reset signal “aa” is a self-resetting signal for self-resetting the counter 114 when the vertical synchronization signal VSYNC is lost due to a weak electric field or the like or nothing is inputted. The self-reset signal “a” and the external reset signal “bb” are outputted from the reset pulse generating section 120 and inputted into the OR gate 130, and output of the OR gate 130 becomes the reset signal COUNTRES.

The count decoder section 110 has a decode selector 111 for controlling the timing of generating the self-reset signal “a”. The decode selector 111 selects a decode value “263” for the NTSC signal when the mode setting signal PALMODE is “Low” (hereinafter referred to as “Lo”), and selects a decode value “313” for the PAL signal when the mode setting signal PALMODE is “High” (hereinafter referred to as “Hi”). These decode values are set to values slightly larger than periods (NTSC: 262. 5H, PAL: 312.5H) of the vertical synchronization signal VSYNC so as to be able to self-reset the counter 114 immediately after loss of the vertical synchronization signal VSYNC. The decode selector 111 outputs a self-reset control signal SEL when a count value of the counter 114 reaches the selected decode value.

The counter 114 further has a decode selector 112 for generating the first noise eliminating signal VSC. The decode selector 112 selects a decode value “240” for the NTSC signal when the mode setting signal PALMODE is Lo, and selects a decode value “280” for the PAL signal when the mode setting signal PALMODE is Hi. In order to prevent input of noise as thoroughly as possible, these decode values are set to such values as to disable input of a signal until just before the timing of arrival of the vertical synchronization signal VSYNC. Specifically, in the present embodiment, the decode values are set to about 90% of the periods (NTSC: 262.5H, PAL: 312.5H) of the vertical synchronization signal VSYNC.

The decode selector 112 outputs the first noise eliminating signal VSC when the counter value of the counter 114 reaches the selected decode value. Specifically, the decode selector 112 outputs the first noise eliminating signal VSC of “Lo”. When the count value of the counter 114 returns to “0”, the decode selector 112 returns the first noise eliminating signal VSC to “Hi”.

### 1.3.2 Configuration of Reset Pulse Generating Section

The reset pulse generating section 120 has a self-reset generating section 121 for generating the self-reset signal “a”, and an external reset generating section 122 for generating the external reset signal “b”. The self-reset generating section 121 and the external reset generating section 122 are synchronized with the counter 114 by inputting the horizontal synchronization signal HSYNC.

An AND gate 123 is connected between the self-reset generating section 121 and the external reset generating section 122. The AND gate 123 inputs the first noise eliminating signal VSC outputted from the decode selector 112 and a second noise eliminating signal “c” outputted from the self-reset generating section 121, to output an input disabling signal “d”. Specifically, the AND gate 123 outputs the input disabling signal “d” of “Hi” when both the first noise eliminating signal VSC and the second noise eliminating signal “c” are Hi, and outputs the input disabling signal “d” of “Lo” when at least either the first noise eliminating signal VSC or the second noise eliminating signal “c” is Lo.

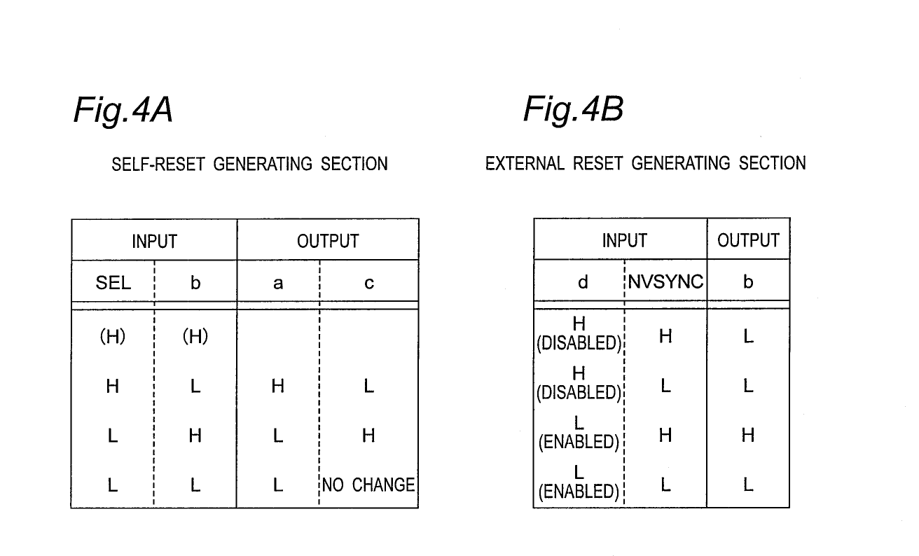

The self-reset generating section 121 inputs the self-reset control signal SEL from the decode selector 111 and the external reset signal “b” from the external reset generating section 122, and outputs the self-reset signal “a” and the second noise eliminating signal “c”. The external reset generating section 122 inputs the inversion signal NVSYNC of the vertical synchronization signal and the input disabling signal “d”, and outputs the external reset signal “b”. FIG. 4A and FIG. 4B show a truth value table for input signals and output signals of the self-reset generating section 121 and the external reset generating section 122, respectively.

FIG. 4A shows a truth value table for the signals SEL and b inputted into the self-reset generating section 121 and the signals a and c outputted by the self-reset generating section 121. Here, since the self-reset control signal SEL is generated when the external reset signal “b” based on arrival of the vertical synchronization signal VSYNC is not generated, the combination of “SEL=H” and “b=H” does not exist.

The self-reset generating section 121 outputs the self-reset signal “a” at the same level as the self-reset control signal SEL inputted from the decode selector 111. That is, the Hi self-reset signal “a” is generated at the timing of input of the Hi self-reset control signal SEL (SEL=H, a=H).

The second noise eliminating signal “c” becomes Lo when the self-reset control signal SEL becomes Hi (SEL=H, c=L), and returns from Lo to Hi when the external reset signal “b” becomes Hi (b=H, c=H). When both the self-reset control signal SEL and the external reset signal “b” are Lo, the level of the second noise eliminating signal “c” remains unchanged.

FIG. 4B shows a truth value table for the signal “d” and NVSYNC which are inputted into the external reset generating section 122, and the signal “b” outputted by the external reset generating section 122. The external reset generating section 122 comes into a state where the input of the inversion signal NVSYNC is acceptable when the input disabling signal “d” that is inputted into the reset terminal is Lo, and comes into a state where the input of the inversion signal NVSYNC is unacceptable when the input disabling signal “d” is Hi.

The external reset signal “b” is outputted when the input disabling signal “d” is Lo at the time of input of the inversion signal NVSYNC (d=L, NYSYNC=H, b=H) The external reset signal “b” is not outputted when the inversion signal NVSYNC is inputted during the Hi input disabling signal “d” (d=H, NYSYNC=H, b=L). As thus described, the Hi input disabling signal “d” that is inputted into the reset terminal of the external reset generating section 122 suspends the output operation of the external reset generating section 122. Thereby, the external reset generating section 122 is prevented from erroneously resetting the counter 114, by outputting the external reset signal “b” at a timing other than the timing of arrival of the vertical synchronization signal VSYNC, due to noise.

### 2. Operation

### 2.1 Setting Color System Based on Frequency Distinction in Video Display Apparatus

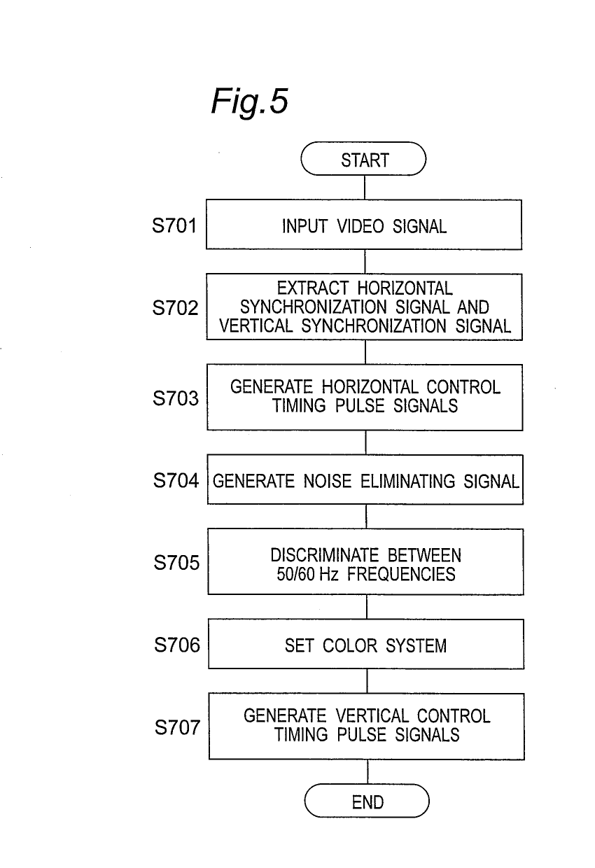

FIG. 5 shows a method for discriminating a frequency of the vertical synchronization signal VSYNC of a video signal, to automatically make a variety of settings in an internal circuit concerning a color system of the vertical frequency distinction circuit 1000 to settings for the PAL mode or the NTSC mode. In FIG. 5, steps S704 and S705 relates to a vertical frequency distinction operation.

When the video display apparatus shown in FIG. 1 inputs a video signal (S701), the synchronization separation circuit 3000 extracts the horizontal synchronization signal HSYNC and the vertical synchronization signal VSYNC from the inputted video signal (S702). The horizontal control pulse generating section 2000 generates the horizontal control timing pulse signals HTPLS based on the horizontal synchronization signal HSYNC (S703).

The vertical frequency distinction circuit 1000 generates, by means of the vertical control pulse generating section 100, the first noise eliminating signal VSC based on the horizontal synchronization signal HSYNC and the vertical synchronization signal VSYNC (S704). The vertical frequency distinction circuit 1000 samples the first noise eliminating signal VSC at the timing of arrival of the vertical synchronization signal VSYNC, to generate the distinction result signal FVDET. By using this distinction result signal FVDET, it is discriminated whether the frequency is 50 Hz or 60 Hz (S705).

The video display apparatus feeds the distinction result signal FVDET back to the mode setting signal PALMODE, thereby enabling automatic setting of the color system of the vertical frequency distinction circuit 1000 for the PAL mode or the NTSC mode (S706). The vertical control pulse generating section 100 generates the vertical control timing pulse signals VTPLS in accordance with the set mode (S707).

As thus described, the video display apparatus discriminates the frequency of the vertical synchronization signal VSYNC of the inputted video signal based on the first noise eliminating signal VSC, to automatically set the color system in accordance with the frequency of the vertical synchronization signal VSYNC to the PAL mode or the NTSC mode. Therefore, even when the input signal is switched from the PAL signal to the NTSC signal or the NTSC signal to the PAL signal halfway through reception of the input signal, the vertical control timing pulse signals VTPLS in accordance with the frequency of the vertical synchronization signal VSYNC of the input signal can be generated.

### 2.2 Generation of Noise Eliminating Signal (Operation of Vertical Control Pulse Generating Section)

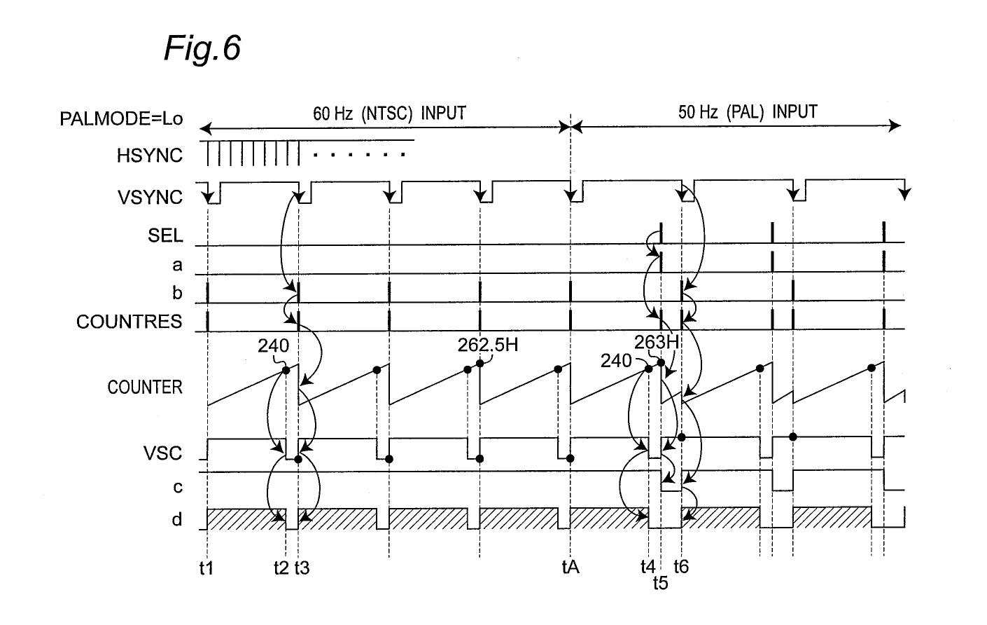

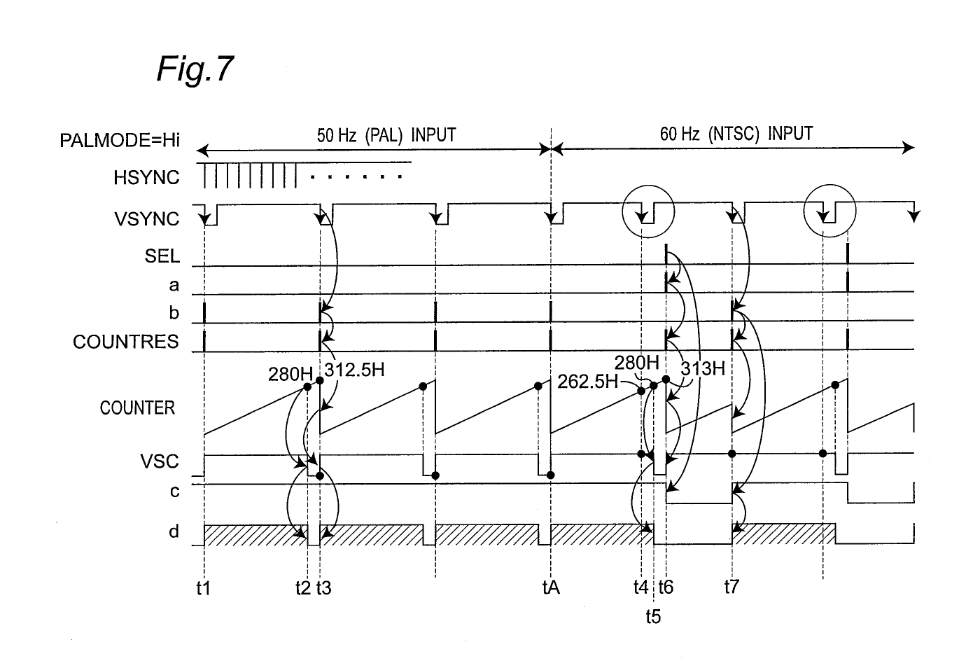

The step of generating the first noise eliminating signal VSC (S704) in FIG. 5 is described in details. FIGS. 6 and 7 show waveforms of main operations of the vertical control pulse generating section 100 shown in FIG. 3. FIGS. 6 and 7 show waveforms associated with generation of the first noise eliminating signal VSC, and ones associated with generation of the vertical control timing pulse signals VTPLS are omitted. FIG. 6 shows waveforms of operations when the Lo mode setting signal PALMODE is inputted into the vertical control pulse generating section 100 (NTSC mode), and FIG. 7 shows waveforms of operations when the Hi mode setting signal PALMODE is inputted into the vertical control pulse generating section 100 (PAL mode).

### 2.2.1 NTSC Mode

The following description is an operation of FIG. 6 performed when the mode setting signal PALMODE is Lo (NTSC mode). When the mode setting signal PALMODE is Lo, the decode selector 111 for self-reset selects a decode value “263”, and the decode selector 112 for generation of a noise eliminating signal selects a decode value “240”. FIG. 6 shows operating waveforms in a case where a video signal in the NTSC system (frequency of 60 Hz, 1 V=262.5H) is inputted until a time tA and a video signal in the PAL system (frequency of 50 Hz, 1 V=312.5H) is inputted after the time tA.

In the case of the NTSC signal, a count value of the horizontal synchronization signal HSYNC during one period of the vertical synchronization signal VSYNC is “262.5”. During input of the NTSC signal, the counter 114 is reset before counting the decode value “263” of the decode selector 111. Therefore, the decode selector 111 does not output the self-reset control signal SEL. Since the self-reset control signal SEL is not inputted into the self-reset generating section 121, the self-reset generating section 121 continues to input the Hi second noise eliminating signal “c” into the AND gate 123 according to the external reset signal “b”. Thereby, only the first noise eliminating signal VSC controls acceptance of input of the inversion signal NVSYNC of the external reset generating section 122.

The counter 114 counts up the horizontal synchronization signal HSYNC (time t1). When the count value of the counter 114 reaches the decode value “240” of the decode selector 112 (time t2), the decode selector 112 shifts the first noise eliminating signal VSC to Lo, and outputs the signal VSC. The AND gate 123, to which the Lo first noise eliminating signal VSC is inputted, outputs the Lo input disabling signal “d”. The external reset generating section 122 shifts to the state where the input of the inversion signal NVSYNC of the vertical synchronization signal VSYNC is acceptable (times t2 to t3).

When the vertical synchronization signal VSYNC arrives, the external reset generating section 122 in the state where the input of the inversion signal NVSYNC is acceptable generates and outputs the external reset signal “b” (time t3). The OR gate 130, to which the external reset signal “b” is inputted, outputs the reset signal COUNTRES. Thereby, the counter 114 is reset and again starts to count up from “0”.

Since the count value of the counter 114 returns to “0”, the decode selector 112 shifts the first noise eliminating signal VSC to Hi (time t3) The AND gate 123, to which the Hi first noise eliminating signal VSC is inputted, shifts the input disabling signal “d” to Hi. The external reset generating section 122, to which the Hi input disabling signal “d” is inputted, shifts to the state where the input of the inversion signal NVSYNC of the vertical synchronization signal VSYNC is unacceptable. The external reset generating section 122 maintains the input unacceptable state until the count value reaches “240” again and the next Lo input disabling signal “d” is inputted. Therefore, even if noise is mixed in the vertical synchronization signal VSYNC line, the external reset signal “b” is not erroneously generated.

The vertical control pulse generating section 100 repeats the above-mentioned operation during input of the NTSC signal. When inputting the PAL signal after the time tA, the vertical control pulse generating section 100 operates in the following manner.

In the case of the PAL signal, a count value of the horizontal synchronization signal HSYNC during one period of the vertical synchronization signal VSYNC is “312.5”. When the count value of the counter 114 reaches the decode value “240” of the decode selector 112 (time t4), the decode selector 112 outputs the Lo first noise eliminating signal VSC. The AND gate 123, to which the Lo first noise eliminating signal VSC is inputted, shifts the input disabling signal “d” to Lo. The external reset generating section 122, to which the Lo input disabling signal “d” is inputted, shifts to the state where the input of the inversion signal NVSYNC of the vertical synchronization signal is acceptable (times t4 to t5).

Since the period of the PAL signal is longer than the period of the NTSC signal, the count value of the counter 114 reaches the decode value “263” of the decode selector 111 for self reset which is set to the NTSC mode (time t5). The decode selector 111 outputs the self-reset control signal SEL. The self-reset generating section 121, to which the self-reset control signal SEL is inputted, outputs the self-reset signal “a”, and also shifts the second noise eliminating signal “c” to Lo.

The OR gate 130, to which the self-reset signal “a” is inputted, outputs the reset signal COUNTRES into the counter 114. Thereby, the counter 114 is reset, and the first noise eliminating signal VSC of the decode selector 112 shifts from Lo to Hi. However, at this time, the self-reset generating section 121, to which the self-reset control signal SEL is inputted, has shifted the second noise eliminating signal “c” from Hi to Lo. Thus, the AND gate 123, to which the Hi first noise eliminating signal VSC and the Lo second noise eliminating signal “c” are inputted, outputs the input disabling signal “d” while keeping it Low. Therefore, the external reset generating section 122 maintains the state where the input of the inversion signal NVSYNC of the vertical synchronization signal is acceptable (times t5 to t6).

Upon arrival of a trailing edge of the vertical synchronization signal VSYNC, the external reset generating section 122 in the state where the input of the inversion signal NVSYNC of the vertical synchronization signal is acceptable outputs the external reset signal “b” (time t6). When receiving the external reset signal “b”, the OR gate 130 outputs the reset signal COUNTRES to the counter 114. The counter 114 is thereby reset.

The self-reset generating section 121 receives the external reset signal “b”, and shifts the second noise eliminating signal “c” from Lo to Hi (time t6). The Hi second noise eliminating signal “c” and the Hi first noise eliminating signal VSC are inputted into AND gate 123, the AND gate 123 outputs the Hi input disabling signal “d”. Thereby, the external reset generating section 122 shifts to the state where the input of the inversion signal NVSYNC is unacceptable. Next, the external reset generating section 122 maintains the input unacceptable state until the count value of the counter 114 reaches the decode value “240” of the decode selector 112 and the first noise eliminating signal VSC shifts to Lo. Therefore, even if noise is inputted during the time until arrival of a next vertical synchronization signal VSYNC, the external reset signal “b” is not erroneously generated. The vertical control pulse generating section 100 repeats the above-mentioned operation after input of the PAL signal.

As thus described, both during the time of input of the NTSC signal and the time of input of the PAL signal, the first noise eliminating signal VSC shifts from Hi to Lo when the count value arrives at the decode value “240” of the decode selector 112. Meanwhile the timing of returning from Lo to Hi differs depending upon whether the input signal is the NTSC signal or the PAL signal. Specifically, when the vertical control pulse generating section 100 is in the NTSC mode, the self-reset is not activated during input of the NTSC signal, and the first noise eliminating signal VSC returns to Hi at the timing according to the external reset signal “b”. However, during input of the PAL signal, the self-reset function that is set in the NTSC mode is activated before arrival of the vertical synchronization signal VSYNC of the PAL signal, the first noise eliminating signal VSC returns to Hi at the timing of the self-reset signal “a”. Therefore, the level of the first noise eliminating signal VSC differs between the NTSC signal and the PAL signal at the time of arrival of the vertical synchronization signal VSYNC (times t3 and t6).

### 2.2.2. PAL Mode

The following description is an operation of FIG. 7 performed when the mode setting signal PALMODE is Hi (PAL mode). When the mode setting signal PALMODE is Hi, the decode selector 111 for self-reset selects a decode value “313”, and the decode selector 112 for a noise eliminating signal selects a decode value “280”. FIG. 7 shows operating waveforms in a case where a video signal in the PAL system (frequency of 50 Hz, 1 V=312.5H) is inputted until the time tA and a video signal in the NTSC system (frequency of 60 Hz, 1 V=262.5H) is inputted after the time tA.

In the case of the PAL signal, a count value of the horizontal synchronization signal HSYNC during one period of the vertical synchronization signal VSYNC is “312. 5H”. During input of the PAL signal, the counter 114 is reset before its count value reaches the decode value “313” of the decode selector 111. Therefore, the decode selector 111 does not output the self-reset control signal SEL. The second noise eliminating signal “c” of the self-reset generating section 121 maintains the Hi state according to the external reset signal “b”. Thereby, only the first noise eliminating signal VSC controls reset of the external reset degenerating section 122.

The counter 114 counts up the horizontal synchronization signal HSYNC (time t1). When the count value of the counter 114 reaches the decode value “280” of the decode selector 112, the decode selector 112 shifts the first noise eliminating signal VSC to Lo (time t2). Thereby, the input disabling signal “d” shifts to Lo, and the external reset generating section 122 shifts to the state where the input of the inversion signal NVSYNC is acceptable (times t2 to t3).

Upon arrival of the vertical synchronization signal VSYNC (time t3), the external reset generating section 122 in the input acceptable state outputs the external reset signal “b”. The counter 114 is reset, and the first noise eliminating signal VSC shifts to Hi. Thereby, the input disabling signal “d” returns to Hi, and the external reset generating section 122 shifts to the state where the input of the inversion signal NVSYNC is unacceptable. The external reset generating section 122 maintains the input unacceptable state until the count value of the counter 114 reaches the decode value “280” of the decode selector 112 again and the first noise eliminating signal VSC shifts to Lo. Therefore, even if noise is inputted during the time until arrival of a next vertical synchronization signal VSYNC, the external reset signal “b” is not erroneously generated.

The vertical control pulse generating section 100 repeats the above-mentioned operation during input of the PAL signal. When inputting the NTSC signal after the time tA, the vertical control pulse generating section 100 operates in the following manner.

In the case of the NTSC signal, a count value of the horizontal synchronization signal HSYNC during one period of the vertical synchronization signal VSYNC is “262.5”. The count value is “262.5” when the next vertical synchronization signal VSYNC arrives after the shift from the PAL signal to the NTSC signal (time t4), and the count value has not reached the decode value “280” of the decode selector 112 for generation of a noise eliminating signal. Therefore, the first noise eliminating signal VSC outputted from the decode selector 112 is still Hi at the time t4. Further, at the time t4, the count value of the counter 114 has not reached the decode value “313” of the decode selector 111 for self-reset, either. Therefore, the decode selector 111 does not output the self-reset control signal SEL. The self-reset generating section 121 does not output the self-reset signal “a”, and keeps the second noise eliminating signal “c” in the Hi state. The AND gate 123 continues to receive the Hi first noise eliminating signal VSC and the Hi second noise eliminating signal “c”, and continues to output the Hi input disabling signal “d”. Thus, the external reset generating section 122 maintains the state where the input of the inversion signal NVSYNC of the vertical synchronization signal VSYNC is unacceptable (times t4 to t5). Therefore, the external reset signal “b” is not outputted at the point of the time t4. Since neither the self-reset signal “a” nor the external reset signal “b” is outputted, the counter 114 is not reset and continues to count up.

When the count value of the counter 114 reaches the decode value “280” of the decode selector 112 (time t5), the decode selector 112 shifts the first noise eliminating signal VSC from Hi to Lo. Thereby, the input disabling signal “d” of the AND circuit 123 shifts from Hi to Lo. The reset of the external reset generating section 122 is canceled, and the external reset generating section 122 shifts to the state where the input of the inversion signal NVSYNC is acceptable (times t5 to t6).

When the count value of the counter 114 reaches the decode value “313” of the decode selector 111, the decode selector 111 outputs the self-reset control signal SEL (time t6). Thereby, the self-reset generating section 121 outputs the self-reset signal “a”, and the counter 114 is reset. Upon reset of the counter 114, the first noise eliminating signal VSC of the decode selector 112 shifts to Hi.

When the self-reset control signal SEL is inputted to the self-reset generating section 121, the self-reset generating section 121 shifts the second noise eliminating signal “c” from Hi to Lo. The Hi first noise eliminating signal VSC and the Lo second noise eliminating signal “c” is inputted into the AND circuit 123. The AND circuit 123 continues to output the Lo input disabling signal “d”. Therefore, the external reset generating section 122 maintains the state where the input of the inversion signal NVSYNC is acceptable (times t6 to t7).

Next, when a trailing edge of the vertical synchronization signal VSYNC arrives (time t7), the external reset generating section 122 in the state where the input of the inversion signal NVSYNC is acceptable outputs the external reset signal “b” to the counter 114 and the self-reset generating section 121. Thereby, the counter 114 is reset, and the self-reset generating section 121 shifts the second noise eliminating signal “c” from Lo to Hi.

Since the time period between the time t6 and the time t7 is shorter than the period of the vertical synchronization signal VSYNC of the NTSC signal, the count value before being reset at the time t7 has not reached the decode value “280” of the decode selector 112. Therefore, the first noise eliminating signal VSC keeps maintaining the Hi state at the point of the time t7.

When the first noise eliminating signal VSC that remains Hi and the second noise eliminating signal “c” that has shifted to Hi are inputted into the AND circuit 123, the input disabling signal “d” output from the AND circuit 123 shifts from Lo to Hi (time t7). Thereby, the external reset generating section 122 shifts to a state where acceptance of the input of the inversion signal NVSYNC is disabled. Hence a next input vertical synchronization signal VSYNC becomes invalid.

As thus described, every other vertical synchronization signal VSYNC becomes invalid during input of the NTSC signal, and the counter 114 is reset alternately by the external reset signal “b” and the self-reset signal “a”. The first noise eliminating signal VSC shifts to Lo at the timing of every other vertical synchronization signal VSYNC. The vertical control pulse generating section 100 repeats the above-mentioned operation during input of the NTSC signal.

As described above, both during the time of input of the PAL signal and the time of input of the NTSC signal, the first noise eliminating signal VSC shifts from Hi to Lo when the count value arrives at the decode value “280” of the decode selector 112 for generation of a noise eliminating signal. Meanwhile the timing of returning from Lo to Hi differs depending upon whether the input signal is the NTSC signal or the PAL signal. Specifically, when the vertical control pulse generating section 100 is in the PAL mode, the self-reset is not activated during input of the PAL signal, and the first noise eliminating signal VSC returns to Hi at the timing according to the external reset signal “b”. However, during input of the NTSC signal, every other vertical synchronization signal VSYNC becomes invalid, and hence the self-reset function set in the PAL mode is activated. Therefore, the first noise eliminating signal VSC returns to Hi at the timing according to the self-reset signal “a”. Accordingly, the level of the first noise eliminating signal VSC differs between the PAL signal and the NTSC signal at the time of arrival of the vertical synchronization signal VSYNC (times t3 and t7).

As thus described, both in the NTSC mode and in the PAL mode, the levels of Hi and Lo of the first noise eliminating signal VSC at the time of arrival of the vertical synchronization signal VSYNC differ depending upon whether the input signal is the NTSC signal or the PAL signal. Therefore, in the present embodiment, discrimination about whether the input signal is the NTSC signal or the PAL signal is performed by detecting the level of the first noise eliminating signal VSC upon arrival of the vertical synchronization signal VSYNC.

### 2.3 Discrimination of frequency (Operations of Distinction Result Latch Section and Output Selecting Section)

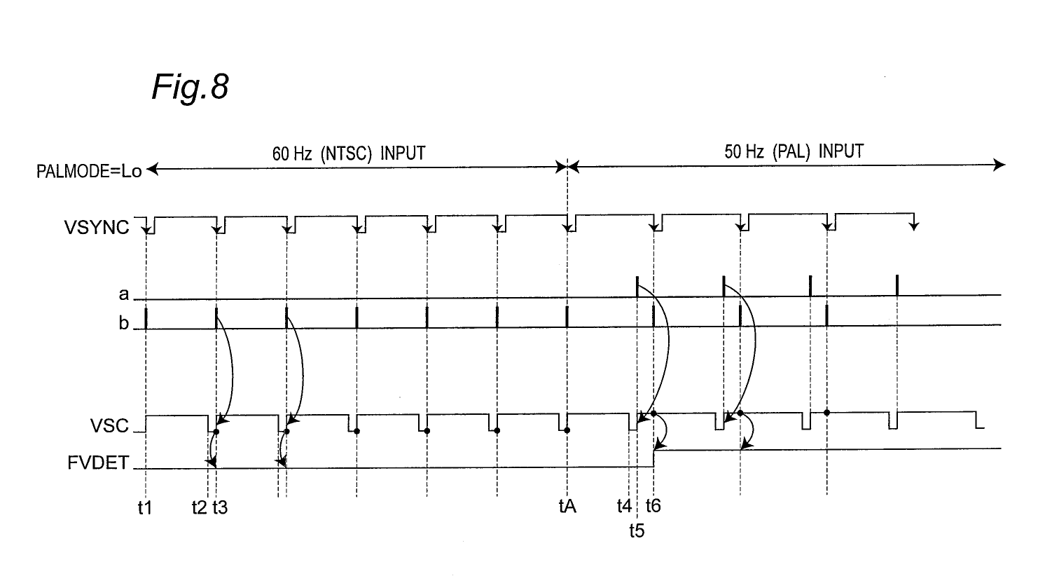

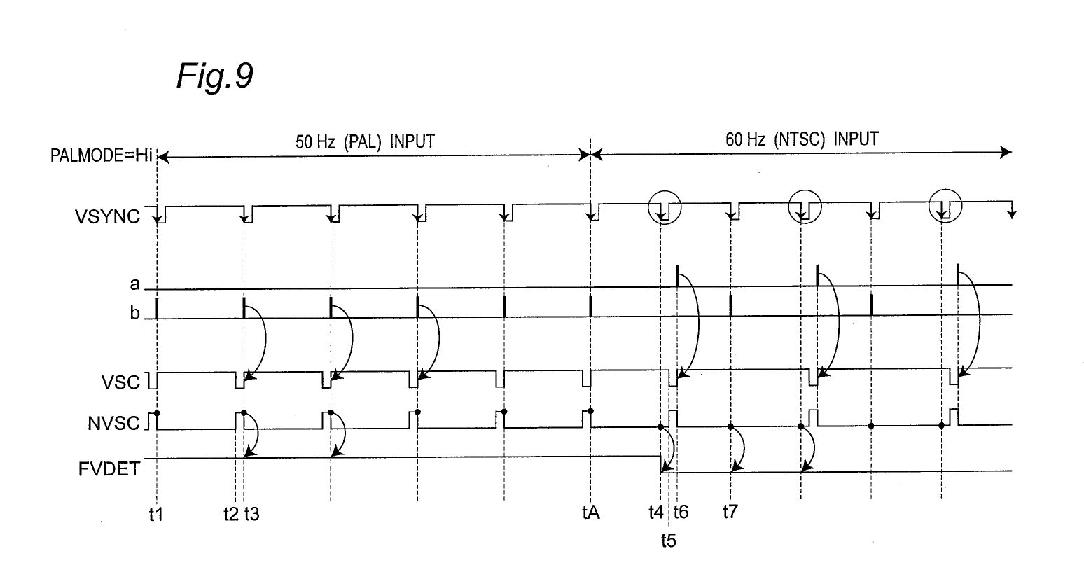

The step (S705) in FIG. 5 of discriminating a frequency based on the first noise eliminating signal VSC is described in details below. FIGS. 8 and 9 show waveforms of the distinction result signal FVDET generated using the first noise eliminating signal VSC shown in FIGS. 6 and 7. FIG. 8 corresponds to FIG. 6, and shows operating waveforms in a case where the mode setting signal PALMODE is Lo (NTSC mode). FIG. 9 corresponds to FIG. 7, and shows operating waveforms in a case where the mode setting signal PALMODE is Hi (PAL mode)

### 2.3.1 NTSC Mode

The following description is an operation of FIG. 8 performed when the mode setting signal PALMODE is Lo (NTSC mode). When the mode setting signal PALMODE is Lo (NTSC mode), a signal that passes through the NAND gate 310 in the output selecting section 300 of FIG. 2 is outputted to the output terminal 40. That is, the output signal of the flip-flop 210 of the discrimination result latch section 200 that is inputted into the NAND gate 310 is outputted to the output terminal 40. The flip-flop 210 samples the first noise eliminating signal VSC inputted in the data input terminal at the timing of leading edge of the inversion signal NVSYNC of the vertical synchronization signal that inputted into the clock terminal, that is, at the timing of trailing edge of the vertical synchronization signal VSYNC shown in FIG. 8.

During input of the NTSC signal in the NTSC mode, as described above, the first noise eliminating signal VSC returns from Lo to Hi at the timing of the external reset signal “b”. The flip-flop 210 outputs, to the NAND gate 310 of the output selecting section 300, the Lo level of the first noise eliminating signal VSC before returning to Hi at the timing of trailing edge of the vertical synchronization signal VSYNC (e.g. time t3). Thereby, the output selecting section 300 outputs the distinction result signal FVDET of the Lo level to the output terminal 40. During input of the NTSC signal, the distinction result signal FVDET is constantly the Lo level.

When the PAL signal is inputted after the time tA, as described above, the first noise eliminating signal VSC returns from Lo to Hi at the timing of the self-reset signal “a”. Therefore, when the vertical synchronization signal VSYNC arrives (e.g. time t6), the first noise eliminating signal VSC is the Hi level. The flip-flop 210 samples this first noise eliminating signal VSC of the Hi level at the timing of trailing edge of the vertical synchronization signal VSYNC, to output the sampled signal to the NAND gate 310 in the output selecting section 300. The output selecting section 300 outputs the distinction result signal FVDET of the Hi level to the output terminal 40. After the PAL signal has been inputted, the distinction result signal FVDET is constantly the Hi level.

As described above, the distinction result signal FVDET is Lo during input of the NTSC signal, and the distinction result signal FVDET changes to Hi when the PAL signal starts to be inputted. It is therefore possible to discriminate change in input signal from the NTSC signal to the PAL signal by the distinction result signal FVDET.

### 2.3.2 PAL Mode

The following description is an operation of FIG. 9 performed when the mode setting signal PALMODE is Hi (PAL mode). When the mode setting signal PALMODE is Hi (PAL mode), a signal that passes through the NAND gate 320 in the output selecting section 300 shown in FIG. 2 is outputted to the output terminal 40. That is, the output signal of the flip-flop 220 of the discrimination result latch section 200 that is inputted into the NAND gate 320 is outputted to the output terminal 40. The flip-flop 220 samples an inversion signal NVSC of the first noise eliminating signal VSC that is inputted through the inverter 230 at the timing of leading edge of the inversion signal NVSYNC of the vertical synchronization signal that is inputted into the clock terminal, that is, at the timing of trailing edge of the vertical synchronization signal VSYNC shown in FIG. 9.

During input of the PAL signal in the PAL mode, as described above, the first noise eliminating signal VSC returns from Lo to Hi at the timing of the external reset signal “b”. That is, the inversion signal NVSC of the first noise eliminating signal VSC which is inverted through the inverter 230 returns from Hi to Lo at the timing of the external reset signal “b”. The flip-flop 220 outputs, to the NAND gate 320 of the output selecting section 300, the Hi level of the inversion signal NVSC before returning from Hi to Lo at the timing of trailing edge of the vertical synchronization signal VSYNC (e.g. time t3). The output selecting section 300 outputs the distinction result signal FVDET of the Hi level to the output terminal 40. During input of the PAL signal, the distinction result signal FVDET is constantly the Hi level.

When the NTSC signal is inputted after the time tA, as described above, the first noise eliminating signal VSC returns from Lo to Hi at the timing of the self-reset signal “a”. Therefore, when the vertical synchronization signal VSYNC arrives (times t4 or t7), the first noise eliminating signal VSC is the Hi level. That is to say, the inversion signal NVSC of the first noise eliminating signal VSC is the Lo level. The flip-flop 220 samples the inversion signal NVSC of the Lo level at the timing of trailing edge of the vertical synchronization signal VSYNC, to output the sampled signal to the NAND gate 320 in the output selecting section 300. The output selecting section 300 outputs the distinction result signal FVDET of the Lo level to the output terminal 40. After the NTSC signal has been inputted, the distinction result signal FVDET is constantly the Lo level.

As described above, both in the NTSC mode and in the PAL mode, the distinction result signal FVDET is Lo during input of the NTSC signal, and the distinction result signal FVDET is Hi during input of the PAL signal. It is thereby possible to discriminate whether the input signal is the NTSC signal or the PAL signal. Therefore, when the input signal is changed from the NTSC signal to the PAL signal in the setting of the NTSC mode (PALMODE=Lo), the setting can be automatically changed to the PAL mode (PALMODE=Hi) by detecting change to the PAL signal. Further, when the input signal is changed from the PAL signal to the NTSC signal in the setting of the PAL mode (PALMODE=Hi), the setting can be automatically changed to the NTSC mode (PALMODE=Lo) by detecting change to the NTSC signal.

### 3. Conclusion

The vertical frequency distinction circuit of the present embodiment generates the first noise eliminating signal VSC that becomes Lo when the count value reaches a predetermined decode value and returns to Hi when the counter 114 is reset, and discriminates whether the input signal is the PAL signal or the NTSC signal by using the first noise eliminating signal VSC. Specifically, by using the difference in level of the first noise eliminating signal VSC between the PAL signal and the NTSC signal at the time of arrival of the vertical synchronization signal VSYNC, the level of the first noise eliminating signal VSC is sampled at the timing of the arrival of the vertical synchronization signal VSYNC by the distinction result latch section 200. Thereby, the distinction between the PAL signal or the NTSC signal is performed. Further, the output selecting section 300 selects output of the discrimination result latch section 200 so as to equalize the levels of the distinction result signals FVDET showing the PAL signal and the NTSC signal respectively in the PAL mode and the NTSC mode. This enables distinction that a Lo signal is the NTSC signal and a Hi signal is the PAL signal.

As thus described, according to the present embodiment, it is possible to discriminate a difference in frequency between the NTSC signal and the PAL signal only by the counter 114 for generating the vertical control timing pulse signals VTPLS that is typically provided in an apparatus for displaying an image. Hence there is no need to provide a counter specifically for discriminating a frequency as having been conventionally provided. It is thereby possible to reduce a circuit size. A chip area can be significantly reduced in the case of integration.

According to the present embodiment, the mode setting signal PALMODE is switched based on the distinction result signal FVDET. Therefore, for example when a received signal is switched from the PAL signal to the NTSC signal in the state of the PAL mode setting, the mode can be automatically switched to the NTSC mode. This allows the timing pulse generating section 113 of the vertical control pulse generating section 100 to generate the vertical control timing pulse signals VTPLS in accordance with the received signal. Accordingly, when the video display apparatus includes the vertical frequency distinction circuit of the present embodiment, even in a case where the PAL signal and the NTSC signal are switched during reception of the signal, a video signal after the switch can be automatically displayed appropriately.

Further, the vertical control pulse generating section 100 of the present invention generates the first noise eliminating signal VSC, to control the input allowable period of the vertical synchronization signal VSYNC so as to be in an unacceptable state during a certain period after the external reset generating section 122 has inputted the vertical synchronization signal VSYNC. This enables prevention of erroneous resetting of the counter 114 even in the case of arrival of a signal with noise mixed therein after arrival of the vertical synchronization signal VSYNC. It is thereby possible to enhance reliability of the first noise eliminating signal VSC. An accurate distinction result signal FVDET in accordance with the input signal can be output.

### 4. Modified Example

It is to be noted that, although the operation at the time of switching from the NTSC signal to the PAL signal in the NTSC mode is described and the operation at the time of switching the PAL signal to the NTSC signal in the PAL mode are described in the present embodiment, it is also possible to discriminate the frequency of the vertical synchronization signal VSYNC even when the input NTSC signal and the input PAL signal are changed in an inverse order. For example, even in a case where the input signal is changed from the PAL signal to the NTSC signal in the NTSC mode or in a case where the input signal is changed from the NTSC signal to the PAL signal in the PAL mode, it is possible to discriminate switching of the frequency of the vertical synchronization signal VSYNC.

In addition, although it is described that the color system setting method of FIG. 5 is executed by the video display apparatus of the present embodiment, the apparatus to realize this method is not limited to the video display apparatus of the present embodiment. Similarly, the circuit for realizing the vertical frequency distinction method including S704 and S705 of FIG. 5 is not limited to the vertical frequency distinction circuit 1000 of the present embodiment. For example, the circuit for realizing the vertical frequency distinction method may be a circuit that generates the first noise eliminating signal VSC by using the counter 114 for generating vertical control timing pulse signals to discriminate the frequency of the vertical synchronization signal VSYNC, without a counter specifically for discriminating a frequency.

Further, although the first noise eliminating signal VSC is sampled at the timing of arrival of the vertical synchronization signal VSYNC in the present embodiment, the timing for sampling the first noise eliminating signal VSC is not limited. The timing may be when the difference can be used in level of the first noise eliminating signal VSC between the PAL signal and the NTSC signal. For example, the first noise eliminating signal VSC may be sampled at timing based on one of the vertical control timing pulse signals VTPLS having a vertical time period.

The vertical frequency distinction circuit of the present invention has the effect of discriminating between the NTSC signal and the PAL signal while reducing a chip area, and is useful for an apparatus and a system for displaying a video signal, and the like.

Although the present invention has been described in connection with specified embodiments thereof, many other modifications, corrections and applications are apparent to those skilled in the art. Therefore, the present invention is not limited by the disclosure provided herein but limited only to the scope of the appended claims. The present disclosure relates to subject matter contained in Japanese Patent Application No. 2006-283641, filed on Oct. 18, 2006, which is expressly incorporated herein by reference in its entirety.

What is claimed is:

1. A vertical frequency distinction circuit, comprising:
a vertical control pulse generating section that includes a counter and generates vertical control timing pulse signals based on output of the counter, the counter counting a horizontal synchronization signal and being reset based on a vertical synchronization signal; and
a frequency distinction unit that discriminates a frequency of the vertical synchronization signal,
wherein the vertical control pulse generating section generates, based on a count value of the counter, a noise eliminating signal for preventing the counter from being reset due to noise during a predetermined period from arrival of a vertical synchronization signal until arrival of a next vertical synchronization signal, and
the frequency distinction unit generates and outputs a distinction result signal that identifies the frequency of the vertical synchronization signal based on the noise eliminating signal.

2. The vertical frequency distinction circuit according to claim 1, wherein
the vertical control pulse generating section further includes a noise eliminating signal generating section which generates a predetermined level of the noise eliminating signal when a count value of the counter reaches a predetermined decode value, and returns the level of the noise eliminating signal to an original level when the counter is reset, and
the predetermined decode value can be switched by a mode setting signal that is inputted from the outside.

3. The vertical frequency distinction circuit according to claim 2, wherein the mode setting signal is switched based on the distinction result signal.

4. The vertical frequency distinction circuit according to claim 1, wherein the frequency distinction unit detects the level of the noise eliminating signal at the timing of arrival of the vertical synchronization signal, to generate the distinction result signal.

5. The vertical frequency distinction circuit according to claim 4, wherein
the frequency distinction unit includes a distinction result latch section, and
the distinction result latch section includes:
a first flip-flop having a data input terminal to which the noise eliminating signal is inputted, and a clock terminal to which the vertical synchronization signal is inputted;
an inverter which inverts the noise eliminating signal to output the inverted eliminating signal; and
a second flip-flop having a data input terminal to which the output signal of the inverter is inputted, and a clock terminal to which the vertical synchronization signal is inputted.

6. The vertical frequency distinction circuit according to claim 5, wherein the frequency distinction unit further includes an output selecting section that selects either an output signal of the first flip-flop or an output signal of the second flip-flop in the distinction result latch section based on a mode setting signal inputted from the outside, to output the selected signal as the distinction result signal.

7. The vertical frequency distinction circuit according to claim 6, wherein the mode setting signal is switched based on the distinction result signal.

8. A video display apparatus, comprising:
a synchronization separation circuit that extracts a horizontal synchronization signal and a vertical synchronization signal from an input signal;
a vertical frequency distinction circuit according to claim 1 that discriminates a frequency of the vertical synchronization signal based on the horizontal synchronization signal and the vertical synchronization signal, and generates vertical control timing pulse signals based on the discrimination result of the frequency; and
a horizontal control pulse generating section that generates horizontal control timing pulse signals based on the horizontal synchronization signal.

9. A vertical frequency distinction method, comprising:
generating a noise eliminating signal for preventing a counter, which is used for generating vertical control pulse signals, from being reset erroneously due to noise during a predetermined period from arrival of a vertical synchronization signal until arrival of a next vertical synchronization signal; and
outputting a distinction result signal that identifies the frequency of the vertical synchronization signal by sampling the noise eliminating signal based on the vertical synchronization signal.
